(19) United States
(12) Patent Application Publication
(10) Pub. No.: US 2025/0311238 A1
(43) Pub. Date: Oct. 2, 2025

(54) SELECTION DEVICE, MANUFACTURING METHOD THEREFOR, AND NON-VOLATILE MEMORY DEVICE COMPRISING SELECTION DEVICE

(71) Applicants: FOUNDATION FOR RESEARCH AND BUSINESS, SEOUL NATIONAL UNIVERSITY OF SCIENCE AND TECHNOLOGY, Seoul (KR); UNIVERSITY-INDUSTRY FOUNDATION(UIF), YONSEI UNIVERSITY, Seoul (KR)

(72) Inventors: Byung Joon Choi, Seoul (KR); Mann Ho Cho, Seoul (KR); Ha Young Lee, Seoul (KR)

(21) Appl. No.: 18/856,851

(22) PCT Filed: Dec. 21, 2022
(86) PCT No.: PCT/KR2022/020990

§ 371 Date: Jun. 6, 2025

(30) Foreign Application Priority Data
Apr. 15, 2022 (KR) 10-2022-0046648

(51) Int. Cl. H10B 63/00; G11C 5/06; H10N 70/00

(52) U.S. Cl. CPC H10B 63/20; G11C 5/06; H10B 63/84; H10N 70/023; H10N 70/826; H10N 70/883

(57) ABSTRACT

The present disclosure provides a selection device including a first electrode, a second electrode spaced apart from the first electrode, and a switching layer disposed between the first electrode and the second electrode, wherein the switching layer including include a first layer portion disposed on the first electrode and a second layer portion disposed between the first layer portion and the second electrode, and the first layer portion and the second layer portion may have different compositions/composition ratios.

### TECHNICAL FIELD

The present invention relates to electronic devices and semiconductor device technology, and more particularly, to a selection device, a manufacturing method therefor, and a nonvolatile memory device comprising the selection device.

### BACKGROUND ART

Recently, the nonvolatile memory market is rapidly expanding due to the increasing demand for portable digital application devices such as smartphones, tablet PCs, and digital cameras. NAND flash memory is a representative programmable nonvolatile memory device, and technologies such as three-dimensional memory structures or multi-level cells (MLC) are being developed to improve recording density. However, as The NAND flash memory reaches its scaling limit, next-generation memory devices such as resistive memory devices (ReRAM), phase-change memory devices (PRAM), or spin-transfer torque magnetic memory devices (STT-MRAM) that use variable resistors whose resistance value may be reversibly changed as non-volatile memory devices which may replace it are attracting attention.

The-mentioned next-generation memory devices are being developed to have a crossbar array structure (or cross-point array structure) in order to increase integration, but in the crossbar array structure, cell-to-cell interference (crosstalk) such as read errors and write errors for cell information occurs due to sneak current occurring between adjacent cells. In particular, the read-out margin is reduced due to the sneak current, and the size expansion of the crossbar array is limited. In order to prevent the operation error caused by the sneak current, research is being conducted to apply a selection device (or selector) within the cell array. As such selection devices, various devices such as PN diodes, OTS (ovonic threshold switches), MIEC (mixed ionic electronic conduction) devices, FAST (field assisted superlinear threshold) devices, MIT (metal-insulator transition) devices, and tunnel barrier diodes have been proposed

However, in the case of PN diodes, there are problems that as stacking of elements is difficult due to the thermal budget caused by the high process temperature, and that a doping process is required, it is difficult to apply to various memory structures. In the case of OTS, there is a problem that it is difficult to control the substance when manufacturing elements based on chalcogenide substances. MIEC devices and FAST devices are devices that contain diffused metals such as Cu, and have disadvantages in terms of process and device stability, and have a thermal budget of about 300° C. or more. MIT devices have a disadvantage in that they have low selectivity due to relatively high off-current. On the other hand, tunnel barrier diodes are devices that utilize the principle of tunneling occurring at high voltage, but have relatively low selectivity.

In order to manufacture memory devices with a three-dimensional structure, a selective device having high non-linearity (i.e., high selectivity) while using a simple structure and substance combination is required. Furthermore, since the selection device is used as a form connected (coupled) to the memory element (memory layer), it must have a current level that may be connected to the memory element, and it needs to have high durability when considering the number of on/off switching times. Furthermore, when considering the usage environment of the memory element, it may be desirable for the selection device to have high temperature stability.

### DISCLOSURE OF THE INVENTION

### Technical Problem

The technological object to be achieved by the present invention is to provide a selection device having high non-linearity (i.e., high selectivity) and excellent durability and high-temperature stability while using a simple structure and substance composition.

Furthermore, the technological object to be achieved by the present invention is to provide a method for manufacturing the above-described selection device. Furthermore, the technological object to be achieved by the present invention is to provide a nonvolatile memory element including the above-described selection device.

The objects to be achieved by the present invention are not limited to the objects mentioned above, and other objects not mentioned may be understood by those skilled in the art from the description below.

### Technical Solution

According to one embodiment of the present invention, there is provided a selection device comprising: a first electrode; a second electrode spaced apart from the first electrode; and a switching layer disposed between the first electrode and the second electrode, and including hafnium nitride as a main component.

The switching layer may be a hafnium nitride layer.

The switching layer may further include oxygen, and the content of the oxygen in the switching layer may be about 15 at % or less.

The switching layer may further include hafnium oxynitride.

The switching layer may include a first layer portion disposed on the first electrode; and a second layer portion disposed between the first layer portion and the second electrode, and the first layer portion and the second layer portion may have different compositions.

The first layer may include hafnium nitride as a main component, and the second layer may include hafnium oxynitride as a main component.

The oxygen content in the second layer may be about 50 at % or less.

The switching layer may have a thickness of about 2 to 20 nm.

The selection device may have bipolar switching characteristics.

According to another embodiment of the present invention, there is provided a manufacturing method of a selection device comprising: forming a first electrode; forming a switching layer including hafnium nitride as a main component on the first electrode; and forming a second electrode on the switching layer.

The switching layer may be formed by an ALD (atomic layer deposition) process.

The switching layer may be formed by a PEALD (plasma enhanced atomic layer deposition) process.

The PEALD process may use a hollow cathode plasma (HCP) source as a plasma source.

The ALD process may include a step of supplying a first precursor which is a source of hafnium (Hf) into a chamber in which the first electrode is arranged; a first purge step for purging the chamber; a step for supplying a second precursor which is a source of nitrogen (N) into the chamber; and a second purge step for purging the chamber.

The first precursor may include TEMAHf [tetrakis (ethylmethylamido) hafnium (IV)].

The second precursor may include NH3.

The switching layer may be a hafnium nitride layer.

The switching layer may further include oxygen, and the content of the oxygen in the switching layer may be about 15 at % or less.

The switching layer may further include hafnium oxynitride.

The switching layer may include a first layer portion disposed on the first electrode and a second layer portion disposed between the first layer portion and the second electrode, and the first layer portion may include hafnium nitride as a main component, and the second layer portion may include hafnium oxynitride as a main component.

According to another embodiment of the present invention, there is provided a nonvolatile memory device comprising: a selection device according to the above-described embodiment; and a memory element electrically connected to the selection device.

The non-volatile memory device may have a crossbar array structure.

The nonvolatile memory element may include a plurality of first wires extending in a first direction; a plurality of second wires extending in a second direction intersecting the plurality of first wires on the plurality of first wires; and a memory cell disposed at each intersection between the plurality of first wires and the plurality of second wires, and wherein the memory cell may include the selection device and the memory element.

### Advantageous Effects

According to embodiments of the present invention, it is possible to implement a selection device having a high selectivity due to high non-linearity while using a simple structure and substance composition, and also having excellent durability and high-temperature stability. In particular, a selection device having a switching layer based on hafnium nitride which is a nitride, having relatively high nonlinearity and excellent bipolar switching characteristics may be easily implemented by using a specific atomic layer deposition (ALD) process, such as a plasma-enhanced ALD process.

A nonvolatile memory element having excellent operating characteristics and high integration may be implemented by applying the selection devices according to the embodiments.

### BRIEF DESCRIPTION OF THE DRAWINGS

FIG. 1 is a cross-sectional view showing a selection device according to one embodiment of the present invention.

FIG. 2 is a cross-sectional view showing a selection device according to another embodiment of the present invention.

FIGS. 3A to 3C are cross-sectional views showing a method for manufacturing a selection device according to one embodiment of the present invention.

FIGS. 4A to 4C are cross-sectional views showing a method for manufacturing a selection device according to another embodiment of the present invention.

FIG. 5 is a drawing for explaining a method for forming a switching layer which may be applied to a manufacturing method of a selection device according to one embodiment of the present invention.

FIG. 6 is a drawing illustrating showing a precursor substance of hafnium (Hf) that may be applied to a method for manufacturing a selection device according to one embodiment of the present invention.

FIG. 7 is a drawing showing a precursor substance of nitrogen (N) which may be applied to a method for manufacturing a selection device according to one embodiment of the present invention.

FIG. 8 is a drawing for explaining a method of forming a switching layer which may be applied to a method for manufacturing a selection device according to one embodiment of the present invention.

FIG. 9 is a graph showing the change in thickness of a switching layer according to an increase in the cycle of an ALD process when forming the switching layer in a method for manufacturing a selection device according to one embodiment of the present invention.

FIG. 10 is a graph showing the results of XRD (X-ray diffraction) analysis for a switching layer formed by an ALD process in an embodiment of the present invention.

FIG. 11 is a drawing showing an HR-TEM (high resolution transmission electron microscopy) image of a switching layer formed by an ALD process in an embodiment of the present invention.

FIG. 12 is a graph showing the results obtained by analyzing the components through AES (Auger electron spectroscopy) depth profiling for a laminated structure of a first electrode and a switching layer formed in a method for manufacturing a selection device according to one embodiment of the present invention.

FIG. 13 is a graph showing the results of XPS (X-ray photoelectron spectroscopy) analysis for a switching layer formed by an ALD process in an embodiment of the present invention.

FIG. 14 is a graph showing the voltage-current density characteristics of a selection device as a log scale according to an embodiment of the present invention.

FIG. 15 is a graph showing the results obtained by evaluating the K factor corresponding to the performance index of a selection device according to one embodiment of the present invention.

FIG. 16 is a graph showing the results obtained by measuring the ON-current of the selection device according to the embodiment described in FIG. 15.

FIG. 17 is a graph showing Schottky emission characteristics in a low electric field region of a selection device according to one embodiment of the present invention.

FIG. 18 is a graph showing hopping conduction characteristics in a high electric field region of a selection device according to one embodiment of the present invention.

FIG. 19 is an energy band diagram for explaining a switching mechanism according to a positive (+) voltage application to a selection device according to one embodiment of the present invention.

FIG. 20 is an energy band diagram for explaining a switching mechanism according to a negative (−) voltage application to a selection device according to one embodiment of the present invention.

FIGS. 21 to 24 are graphs showing the results obtained by evaluating the current-voltage (I-V) characteristics of a selection device including a switching layer according to embodiments of the present invention.

FIG. 25 is a perspective view illustrating a nonvolatile memory device including a selection device according to one embodiment of the present invention.

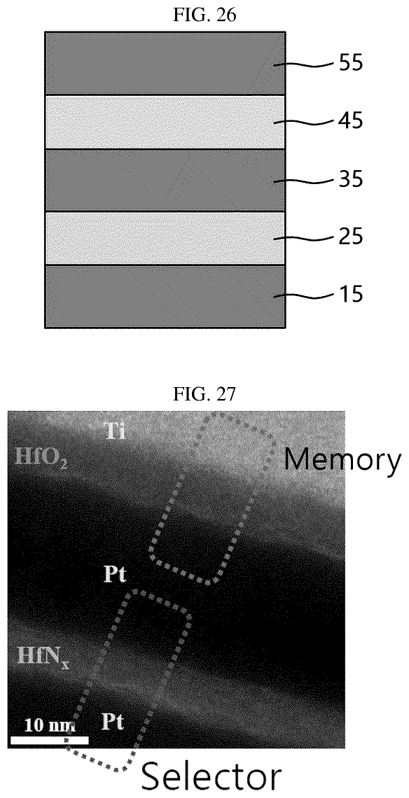

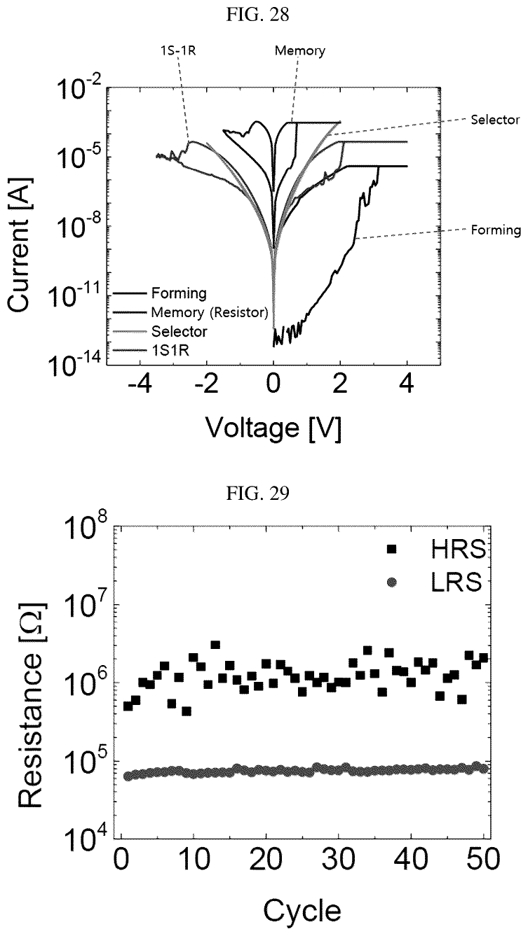

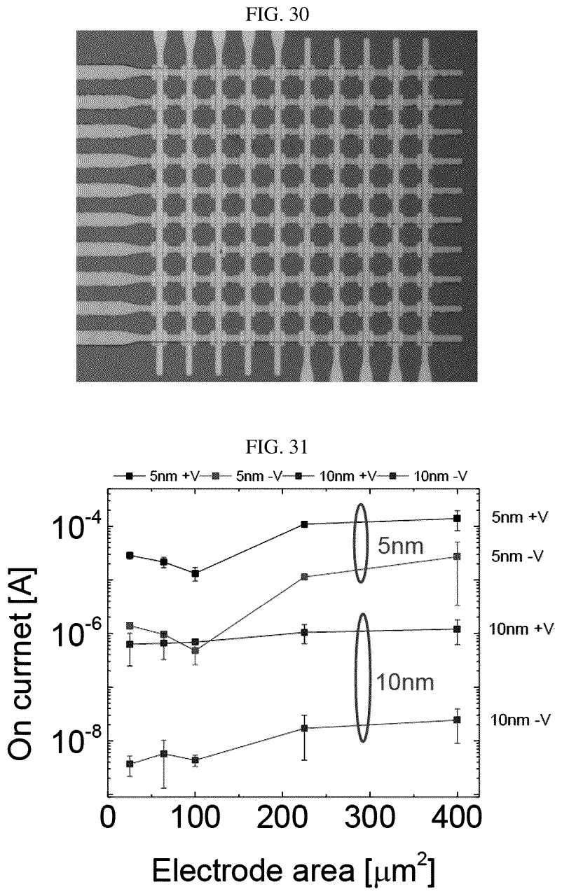

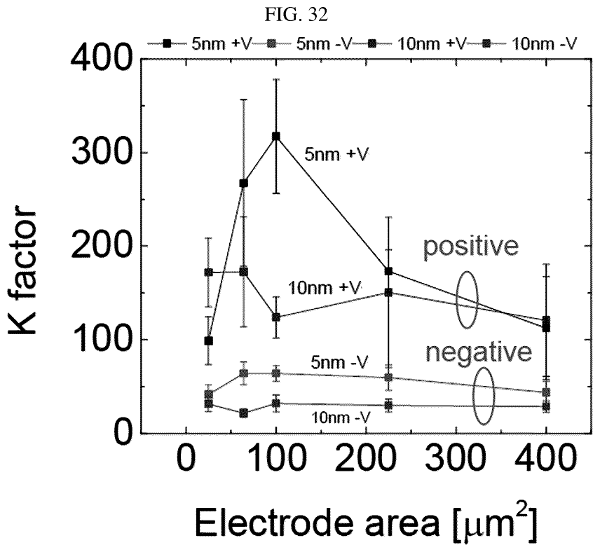

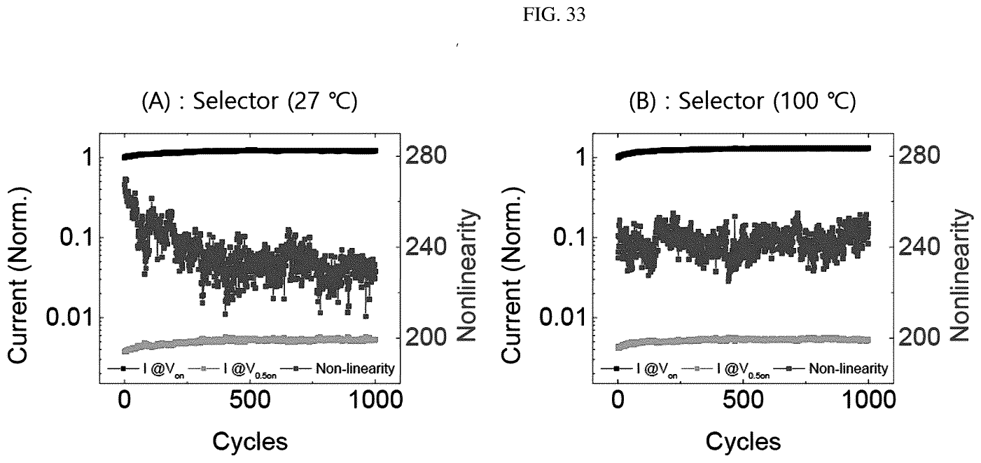

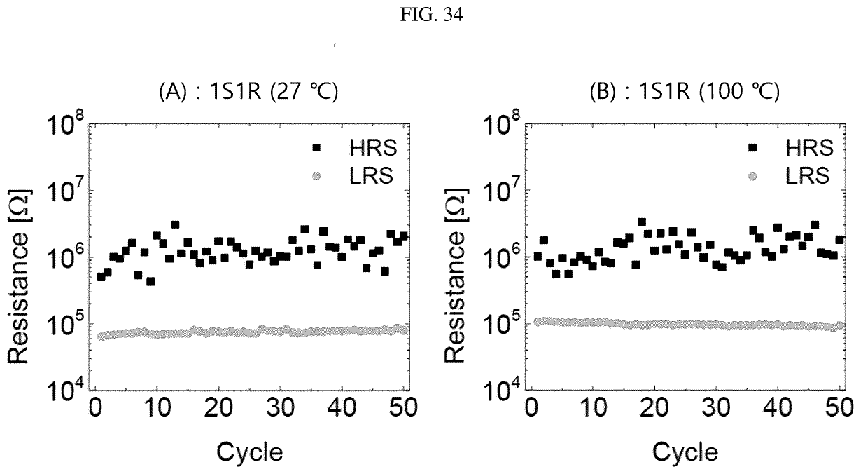

FIG. 2 is a cross-sectional view illustrating a stacked structure which may be included in the memory cell in FIG. 25.

FIG. 27 is a transmission electron microscopy (TEM) image showing a nonvolatile memory device including a selection device according to one embodiment of the present invention.

FIG. 28 is a graph showing the current-voltage (I-V) characteristics of each of the selection devices, memory elements, and the 1S1R structure (i.e., integrated element structure) connected (coupled) to them described in FIG. 27.

FIG. 29 is a graph showing a resistance change characteristics according to the increase in a switching cycle of the 1S1R structure in which the selection device and the memory element described in FIG. 27 are combined.

FIG. 30 is a planar image showing a crossbar array structure including a selection device according to one embodiment of the present invention.

FIG. 31 is a graph showing the change in ON-current according to the electrode size of the selection device in the array structure described in FIG. 30.

FIG. 32 is a graph showing the change in K factor according to the electrode size of the selection device in the array structure described in FIG. 30.

FIG. 33 is a graph showing the results obtained by evaluating the thermal stability of a selection device according to one embodiment of the present invention.

FIG. 34 is a graph showing the results obtained by evaluating the thermal stability of a 1S1R structure (a memory element) including a selection device according to one embodiment of the present invention.

### BEST MODE FOR CARRYING OUT THE INVENTION

Hereinafter, the embodiments of the present invention will be described in detail with reference to the accompanying drawings.

The embodiments of the present invention to be described below are provided to more clearly explain the present invention to those having common knowledge in the related art, and the scope of the present invention is not limited by the following embodiments. The following embodiment may be modified in many different forms.

The terminology used herein is used to describe specific embodiments, and is not used to limit the present invention. As used herein, terms in the singular form may include the plural form unless the context clearly dictates otherwise. Also, as used herein, the terms “comprise” and/or “comprising” specifies presence of the stated shape, step, number, action, member, element and/or group thereof; and does not exclude presence or addition of one or more other shapes, steps, numbers, actions, members, elements, and/or groups thereof. Furthermore, the term “connection” as used herein is a concept that includes not only that certain members are directly connected, but also a concept that other members are further interposed between the members to be indirectly connected.

Furthermore, in the present specification, when a member is said to be located “on” another member, this includes not only a case in which a member is in contact with another member but also a case in which another member is present between the two members. As used herein, the term “and/or” includes any one and any combination of one or more of those listed items. Furthermore, as used herein, terms such as “about”, “substantially”, etc. are used as a range of the numerical value or degree, in consideration of inherent manufacturing and substance tolerances, or as a meaning close to the range. Furthermore, accurate or absolute numbers provided to aid the understanding of the present application are used to prevent an infringer from using the disclosed present invention unfairly.

Hereinafter, the embodiments of the present invention will be described in detail with reference to the accompanying drawings. The size or the thickness of the regions or the parts illustrated in the accompanying drawings may be slightly exaggerated for clarity and convenience of description. The same reference numerals refer to the same elements throughout the detailed description.

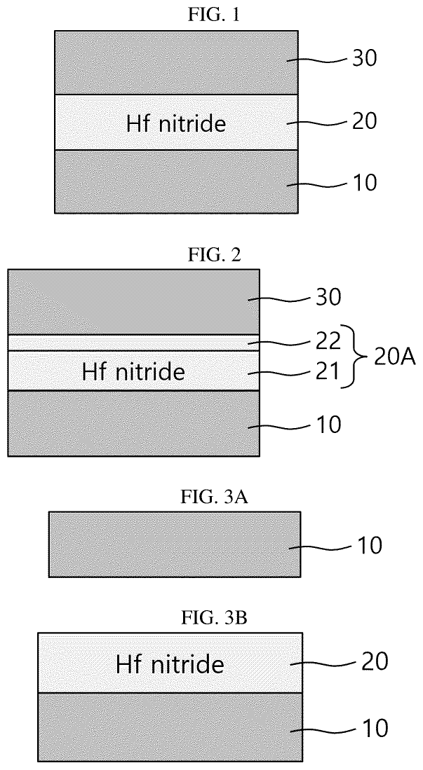

FIG. 1 is a cross-sectional view showing a selection device according to one embodiment of the present invention.

Referring to FIG. 1, a selection device according to an embodiment of the present invention may include a first electrode 10, a second electrode 30 spaced apart from the first electrode 10, and a switching layer 20 disposed between the first electrode 10 and the second electrode 30. The switching layer 20 may include hafnium nitride (Hf nitride) as a main component. The content of hafnium nitride (Hf nitride) in the switching layer 20 may be about 60% (wt %) or more, about 70% (wt %) or more, or about 80% (wt %) or more. The content of hafnium nitride (Hf nitride) in the switching layer 20 may be about 100% (wt %) or more. In this case, the switching layer 20 may be referred to as a hafnium nitride layer. Hafnium nitride (Hf nitride) included in the switching layer 20 may be expressed as HfNₓ, where x may satisfy 0.7<x≤2. In the HfNₓ, the ratio of Hf and N(Hf:N) may be a stoichiometric level of about 1:1 or a level similar thereto, but the present invention is not limited thereto, and the content of nitrogen relative to hafnium may be excessive or insufficient. Additionally, hafnium nitride (Hf nitride) included in the switching layer 20 may basically have the properties of a dielectric rather than a conductor.

The switching layer 20 may further include oxygen (i.e., oxygen atoms). In this case, the content of the oxygen in the switching layer 20 may be about 15 at % or less, about 10 at % or less, or about 5 at % or less. Furthermore, the switching layer 20 may further include hafnium oxynitride and hafnium oxide which are formed by the oxygen. The hafnium oxynitride may be expressed as HfOₓN_{y}, where x may satisfy 1<x≤3, and y may satisfy 2<y≤5. The hafnium oxide may be expressed as HfOₓ, where x may satisfy 1.5<x≤2.

The switching layer 20 may be a layer formed by an atomic layer deposition (ALD) process. More preferably, the switching layer 20 may be a layer formed by a plasma enhanced atomic layer deposition (PEALD) process. Meanwhile, the thickness of the switching layer 20 may be about 2 to 20 nm. When the thickness of the switching layer 20 is less than 2 nm, an insulation breakdown may occur, and when the thickness of the switching layer 20 exceeds 20 nm, it exhibits low current level and non-linearity, resulting in unsuitable characteristics as a selection device. In the range of 2 to 20 nm, the switching layer 20 may exhibit better switching characteristics.

The first electrode 10 and the second electrode 30 may be formed by a metal or a metal compound. For example, the first electrode 10 and the second electrode 30 may be configured to include at least one of platinum (Pt), gold (Au), palladium (Pd), rhodium (Rh), titanium (Ti), tantalum (Ta), copper (Cu), aluminum (Al), nickel (Ni), and tungsten (W). Furthermore, in some cases, the first electrode 10 and the second electrode 30 may be configured to include at least one of a conductive nitride such as TiN or TaN or various conductive oxides. Furthermore, the substances of the first electrode 10 and the second electrode 30 may vary. The substances of the first electrode 10 and the second electrode 30 may be the same or different. Furthermore, the first electrode 10 and the second electrode 30 may have a single-layer structure or a multi-layer structure.

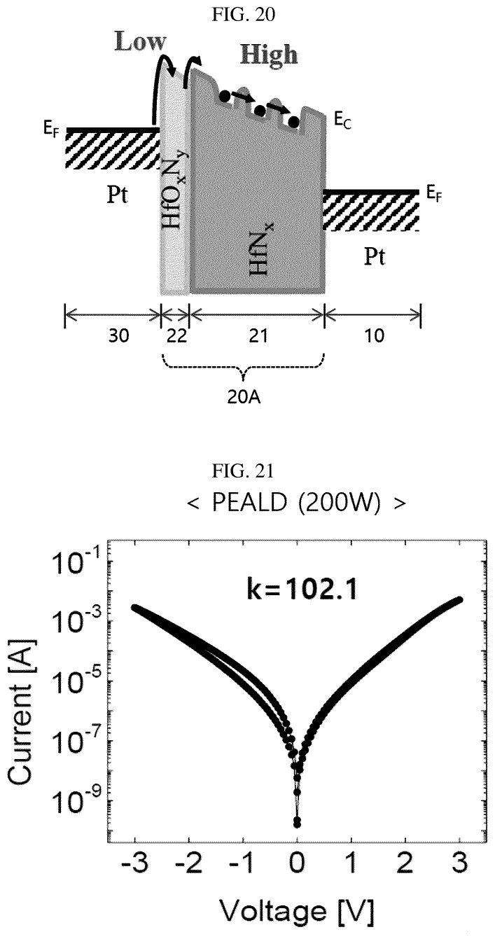

The selection device according to the above-described embodiment may have bipolar switching characteristics. That is, the selection device may have bipolar (two-way) switching characteristics. The selection device may exhibit a switching operation for a positive (+) voltage applied between the first electrode 10 and the second electrode 30, and may also exhibit an opposite switching characteristic for a negative (−) voltage applied between the first electrode 10 and the second electrode 30. Therefore, the selection device may be more usefully applied to various memory elements. The bipolar switching characteristics will be described in more detail later with reference to FIGS. 19 and 20, and so on.

FIG. 2 is a cross-sectional view showing a selection device according to another embodiment of the present invention.

Referring to FIG. 2, the selection device according to the present embodiment may include a first electrode 10, a second electrode 30, and a switching layer 20A disposed therebetween. The switching layer 20A may include hafnium nitride (Hf nitride) as a main component. The content of hafnium nitride (Hf nitride) in the switching layer 20A may be about 60% (wt %) or more, about 70% (wt %) or more, or about 80% (wt %) or more.

The switching layer 20A may include a first layer portion 21 disposed on a first electrode 10 and a second layer portion 22 disposed between the first layer portion 21 and the second electrode 30. Here, the first layer portion 21 and the second layer portion 22 may have different compositions or composition ratios. The first layer portion 21 may include hafnium nitride (Hf nitride) as a main component. The second layer 22 may include hafnium oxynitride as a main component. The content of oxygen (oxygen atoms) in the second layer 22 may be about 50 at % or less, about 40 at % or less, or about 20 at % or less. The entirety of the second layer 22 or its surface may be an oxygen-rich region.

The first layer 21 may further include at least one of hafnium oxynitride and hafnium oxide as a secondary component. Furthermore, the second layer 22 may further include at least one of hafnium nitride and hafnium oxide as a secondary component.

The switching layer 20A may be a layer formed by an ALD process. More preferably, the switching layer 20A may be a layer formed by a PEALD process. The thickness of the switching layer 20A may be about 2 to 20 nm. The selection device according to the present embodiment may have bipolar switching characteristics.

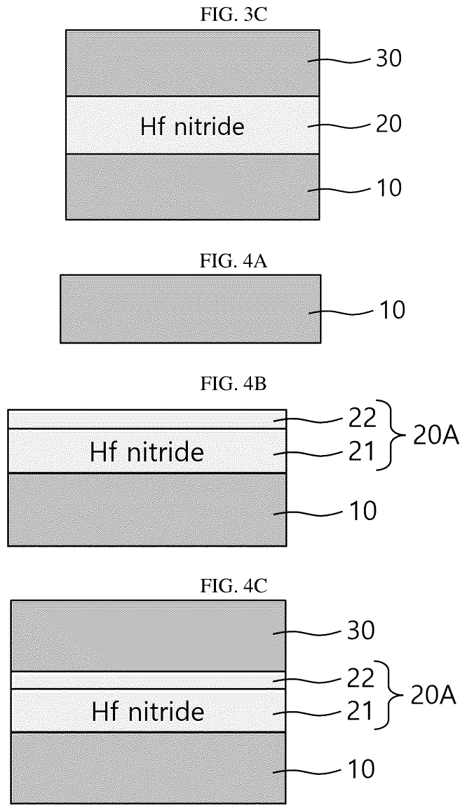

FIGS. 3A to 3C are cross-sectional views showing a method for manufacturing a selection device according to one embodiment of the present invention.

Referring to FIG. 3A, a first electrode 10 may be formed on a predetermined substrate (not shown). The first electrode 10 may be formed to include at least one of a metal and a metal compound, and may be formed by various thin film deposition methods such as PVD (physical vapor deposition) or CVD (chemical vapor deposition).

Referring to FIG. 3B, a switching layer 20 including hafnium nitride (Hf nitride) as a main component may be formed on the first electrode 10. The content of hafnium nitride (Hf nitride) in the switching layer 20 may be about 60% (wt %) or more, about 70% (wt %) or more, or about 80% (wt %) or more. The switching layer 20 may further include oxygen (i.e., oxygen atoms). In this case, the content of the oxygen in the switching layer 20 may be about 15 at % or less, about 10 at % or less, or about 5 at % or less. Furthermore, the switching layer 20 may further include hafnium oxynitride and/or hafnium oxide formed by the oxygen. The specific substance and properties of the switching layer 20 may be the same as those of the switching layer 20 described in FIG. 1.

The switching layer 20 may be formed by an ALD process. More preferably, the switching layer 20 may be formed by a PEALD process. At this time, the PEALD process may use a HCP (hollow cathode plasma) source as a non-limiting example of a plasma source. When the HCP source is used, the inflow of oxygen may be suppressed/prevented, and a high-density plasma may be formed. The oxygen content of the switching layer 20 may be significantly reduced, and a switching layer 20 having crystallinity and excellent uniformity may be formed by using this PEALD process. Accordingly, a switching layer 20 having excellent switching characteristics may be obtained. Furthermore, when utilizing the PEALD process using The HCP source, since the formation of HfOₓN_{y} may be suppressed on the surface (upper surface) of the switching layer 20, it is possible to implement symmetrical operating characteristics of the device according to voltage polarity.

In The PEALD process, the power for plasma generation may be preferably about 150 W to 350 W. Furthermore, the process temperature of the PEALD process may be about 200° C. to 300° C. When these power and temperature conditions are satisfied, it may be advantageous in order to form a switching layer 20 having excellent film quality and high selectivity (i.e., high nonlinearity).

Referring to FIG. 3C, a second electrode 30 may be formed on the switching layer 20. The second electrode 30 may be formed to include at least one of a metal and a metal compound, and may be formed by various thin film deposition methods such as PVD or CVD.

FIGS. 4A to 4C are cross-sectional views showing a method for manufacturing a selection device according to another embodiment of the present invention.

Referring to FIG. 4A, a first electrode 10 may be formed on a predetermined substrate (not shown). The formation of the first electrode 10 may be the same as described in FIG. 3A.

Referring to FIG. 4B, a switching layer 20A including hafnium nitride (Hf nitride) as a main component may be formed on the first electrode 10. The content of hafnium nitride (Hf nitride) in the switching layer 20A may be about 60% (wt %) or more, about 70% (wt %) or more, or about 80% (wt %) or more. The switching layer 20A may include a first layer portion 21 disposed on the first electrode 10 and a second layer portion 22 disposed on the first layer portion 21. Here, the first layer portion 21 and the second layer portion 22 may have different compositions. The first layer portion 21 may include hafnium nitride (Hf nitride) as a main component. The second layer 22 may include hafnium oxynitride as a main component. The content of oxygen, i.e., oxygen atoms, in the second layer 22 may be about 50 at % or less, or about 40 at % or less, or about 20 at % or less. The specific substance and characteristics of the switching layer 20A may be the same as those of the switching layer 20A described in FIG. 2.

The switching layer 20A may be formed by an ALD process. More preferably, the switching layer 20A may be formed by a PEALD process. Depending on the conditions of the ALD process or the conditions of the PEALD process, the substance composition of the switching layer 20A may be controlled. In some cases, the switching layer 20A may also be formed by a thermal ALD process.

Referring to FIG. 4C, a second electrode 30 may be formed on the switching layer 20A. With regard to the formation of the second electrode 30, reference may be made to what was described in FIG. 3c.

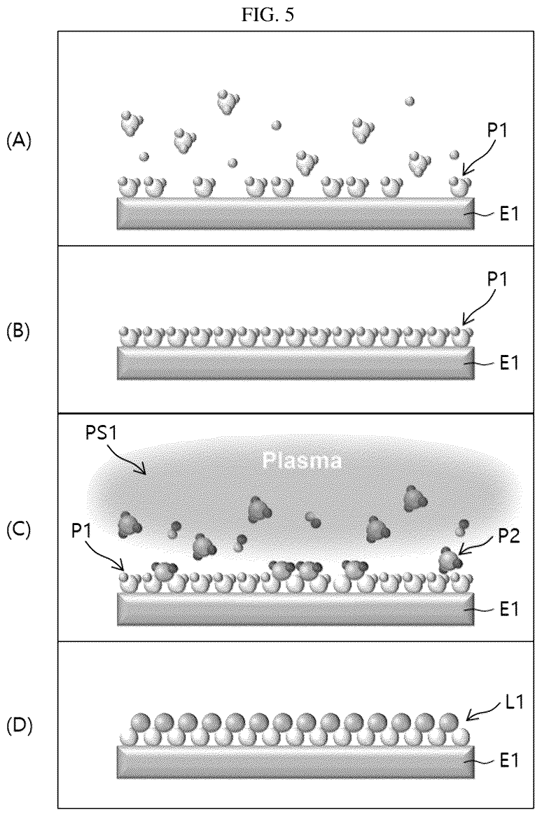

FIG. 5 is a drawing for explaining a method for forming a switching layer which may be applied to a manufacturing method of a selection device according to one embodiment of the present invention. The method for forming the switching layer illustrated in FIG. 5 uses the above-described PEALD process.

Referring to FIG. 5, the method for forming a switching layer using the PEALD process may include a step for supplying a first precursor P1 which is a source of hafnium (Hf) into a chamber in which a first electrode El is arranged to form a hafnium-containing layer on the first electrode E1 [drawing (A)], a first purge step for purging the chamber [drawing (B)], a step for supplying a second precursor P2 which is a source of nitrogen (N) into the chamber in a plasma state to form a reaction layer of the hafnium-containing layer and the nitrogen [drawing (C)], and a second purge step for purging the chamber [drawing (D)]. In the step for supplying the second precursor P2 [(C) drawing], plasma PS1 may be supplied together with the second precursor P2 within the chamber. In the (D) drawing, the reference numeral L1 represents a unit layer (a thin film) formed on the first electrode E1, and the unit layer (a thin film) may correspond to a substance layer constituting the switching layer.

The step for supplying the first precursor P1, the first purge step, the step for supplying the second precursor P2, and the second purge step may correspond to a cycle (1 cycle) for forming the switching layer, and the cycle may be performed repeatedly.

As a non-limiting example, the PEALD process may use a HCP (hollow cathode plasma) source as a plasma source. When the HCP source is used, the inflow of oxygen may be suppressed/prevented, and a high-density plasma may be formed. When using this PEALD process, the oxygen content of the switching layer may be significantly reduced, and a switching layer having crystallinity and excellent uniformity may be easily formed. Furthermore, when utilizing the PEALD process using The HCP source, since the formation of HfOₓN_{y} may be suppressed on the surface (upper surface) of the switching layer, it is possible to implement symmetrical operating characteristics of the device according to voltage polarity.

In the PEALD process, the power for plasma generation may be preferably about 150 W to 350 W. Furthermore, the process temperature of the PEALD process may be about 200° C. to 300° C. When these power and temperature conditions are satisfied, it may be advantageous in order to form a switching layer having excellent film quality and high selectivity (i.e., high nonlinearity).

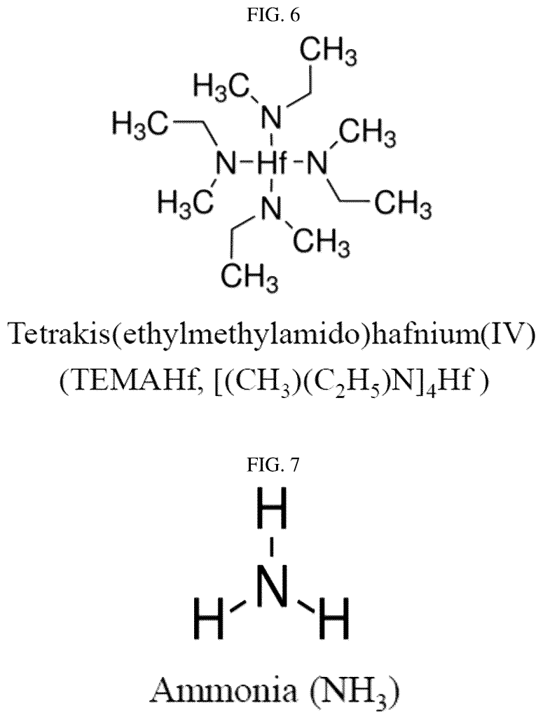

FIG. 6 is a drawing illustrating showing a precursor substance of hafnium (Hf) that may be applied to a method for manufacturing a selection device according to one embodiment of the present invention.

Referring to FIG. 6, a precursor substance of hafnium (Hf) which may be applied to a method for manufacturing a selection device according to an embodiment of the present invention may be, for example, TEMAHf [tetrakis(ethylmethylamido)hafnium (IV)] or may include it. The TEMAHf may correspond to the first precursor P1 of FIG. 5. The Hf precursor substance may be or include TDMAHf [tetrakis(dimethylamino)hafnium]. TDMAHf may correspond to the first precursor P1 of FIG. 5. TDEAHf [tetrakis(diethylamido)hafnium] may be or include it. TDEAHf may correspond to the first precursor P1 of FIG. 5. In addition to TEMAHf and TDMAHf, Hafnium precursor substances such as Hafnium(IV) chloride, Hafnium(IV) iodide, Hafnium isopropoxide isopropanol adduct, Hafnium(IV) fluoride, Hafnium(IV) bromide, Tetrakis (diethylamido) hafnium(IV), Tetrakis(dimethylamido)hafnium(IV), Hafnium(IV) n-butoxide, Hafnium(IV)carbide, Hafnium(IV)oxychloride hydrate, Bis(cyclopentadienyl)hafnium(IV)dichloride, Bis(cyclopentadienyl)dimethylhafnium, Bis(ethylcyclopentadienyl hafniumdichloride, Bis(pentamethylcyclopentadienyl)hafnium dichloride, Bis(i-propylcyclopentadienyl)hafnium dichloride, Hafnium(IV) trifluoromethanesulfonate hydrate, Hafnium carboxyethyl acrylate, Hafnium(IV) tetra-butoxide, Hafnium(IV)acetylacetonate, Dimethylbis(cyclopentadienyl)hafnium(IV), Dimethylbis (t-butylcyclopentadienyl)hafnium(IV), Cyclopentadienylhafnium(IV) truchloride, Indenylhafnium(IV) Trichloride, Hafnium(IV) dichloride oxide octahydrate, Hafnium (IV)ethoxide, Hafnium(IV)i-propoxide monoisopropylate, Pentamethylcyclentadienylhafnium trichloride, i-propylcyclopentadienylhafnium trichloride Tetrabenzylhafnium, Tetrakis(2,2,6,6-tetramethyl-3,5-heptanedionato)hafnium(IV), Tris(dimethylamido)cyclopentadienyl Hafnium may be applied.

FIG. 7 is a drawing showing a precursor substance of nitrogen (N) which may be applied to a method for manufacturing a selection device according to one embodiment of the present invention.

Referring to FIG. 7, a precursor substance of nitrogen (N) that may be applied to a method for manufacturing a selection device according to an embodiment of the present invention may be, for example, NH₃ (ammonia) or may include it. The NH₃ may correspond to the second precursor P2 of FIG. 5. The nitrogen precursor substance may be N₂ (Nitrogen) or may include it. The N₂ may correspond to the second precursor P2 of FIG. 5. It may be or include a N₂+H₂ mixed gas. The N₂+H₂ mixed gas may also correspond to the second precursor P2 of FIG. 5. The nitrogen precursor substance may be or include N₂+H₂ (hydrazine). It may include NH₃, N₂, N₂+H₂, N₂H₄ gas or a plasma gas of a mixed gas thereof.

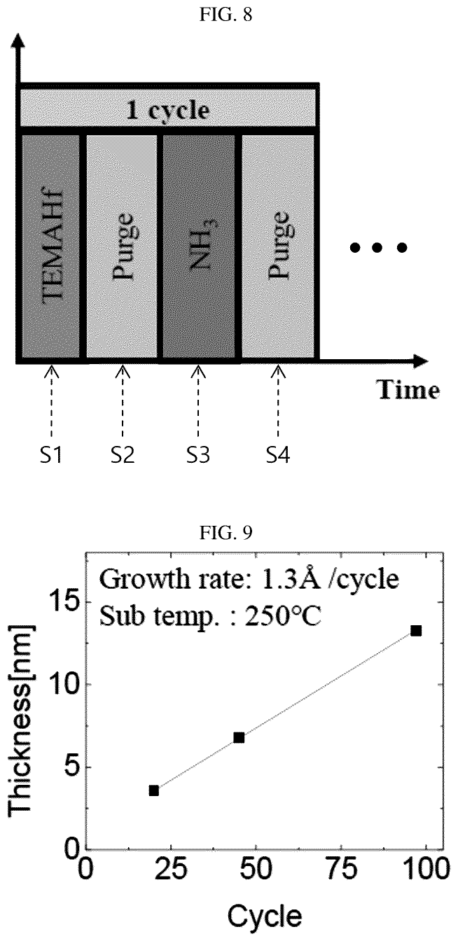

FIG. 8 is a drawing for explaining a method of forming a switching layer which may be applied to a method for manufacturing a selection device according to one embodiment of the present invention.

Referring to FIG. 8, when forming a switching layer by an ALD process or a PEALD process, a cycle of the ALD process or a PEALD process may include a step S1 for supplying a first precursor which is a source of hafnium (Hf) into a chamber in which a first electrode is arranged to form a hafnium-containing layer on the first electrode E1, a first purge step S2 for purging the chamber, a step S3 for supplying a second precursor which is a source of nitrogen (N) into the chamber to form a reaction layer of the hafnium-containing layer and the nitrogen, and a second purge step S4 for purging the chamber. Here, the first precursor may include TEMAHf, and the second precursor may include NH₃.

The duration of the S1 stage may be, for example, about 0.5 sec to 3 sec, the duration of the S1 stage may be, for example, about 0.5 sec to 3 sec, the duration of the S2 stage may be, for example, about 10 sec to 60 sec, the duration of the S3 stage may be, for example, about 1 sec to 10 sec, and the duration of the S4 stage may be, for example, about 20 sec to 100 sec. As a more specific example, the duration of step S1 may be, for example, about 1 sec to 1.5 sec, the duration of step S2 may be, for example, about 15 sec to 30 sec, the duration of step S3 may be, for example, about 5 sec to 6 sec, and the duration of step S4 may be, for example, about 45 sec to 60 sec. However, the durations of steps S1 to S4 may vary depending on the case.

As shown in FIGS. 6 to 8, when TEMAHf is used as the first precursor and NH₃ is used as the second precursor, it may be advantageous in forming a switching layer having excellent switching characteristics. However, in the embodiment of the present invention, the substance of the first precursor and the substance of the second precursor are not limited to TEMAHf and NH₃, and various other substances may be applied.

FIG. 9 is a graph showing the change in thickness of a switching layer according to an increase in the cycle of an ALD process when forming the switching layer in a method for manufacturing a selection device according to one embodiment of the present invention. Referring to FIG. 9, the growth rate of the switching layer in the ALD process was approximately 1.3A/cycle. At this time, the temperature of the substrate was 250° C. The temperature of the substrate is exemplary, and the temperature of the substrate in the ALD process may be in the range of 100° C. to 350° C.

FIG. 10 is a graph showing the results of XRD (X-ray diffraction) analysis for a switching layer formed by an ALD process in an embodiment of the present invention.

Referring to FIG. 10, it may be confirmed that the switching layer formed by the ALD process in the embodiment of the present invention is a substance layer containing hafnium nitride (HfNx) as a main component, and is a polycrystalline phase of mononitride having a main peak of (111) and other crystal planes of (200), (220), (311), and (222).

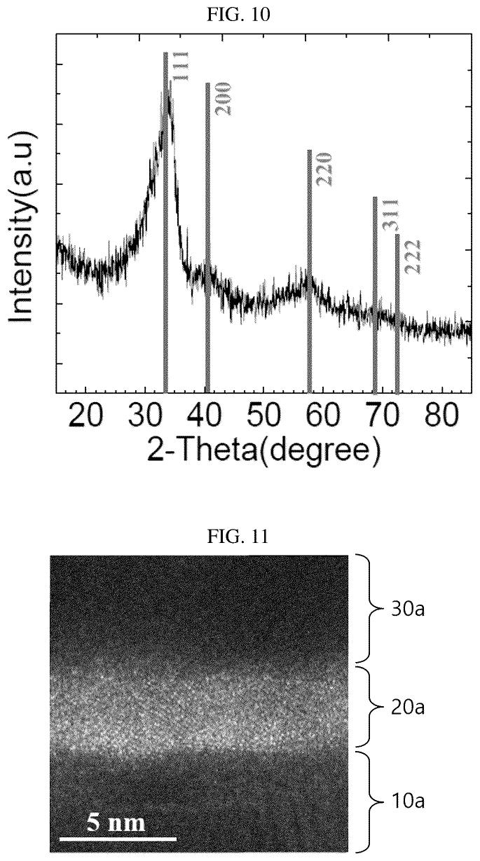

FIG. 11 is a drawing showing an HR-TEM (high resolution transmission electron microscopy) image of a switching layer 20A formed by an ALD process in an embodiment of the present invention. In FIG. 11, the reference numeral 10a represents a first electrode, and the reference numeral 30a represents a second electrode.

Referring to FIG. 11, it may be confirmed that the switching layer 20A formed (grown) by the ALD process in the embodiment of the present invention is a substance layer including hafnium nitride (HfNₓ) as a main component, and this substance layer has a predetermined crystal structure and is grown fairly uniformly.

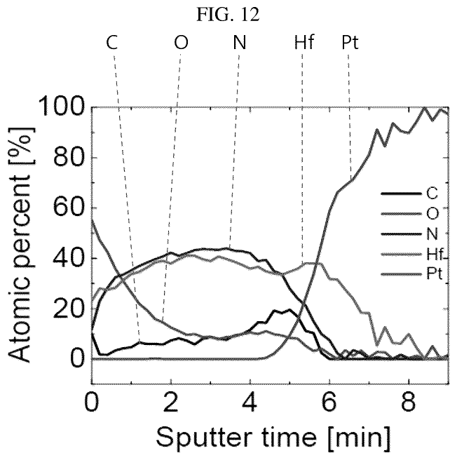

FIG. 12 is a graph showing the results obtained by analyzing the components through AES (Auger electron spectroscopy) depth profiling for a laminated structure of a first electrode and a switching layer formed in a method for manufacturing a selection device according to one embodiment of the present invention. FIG. 12 may be said to be the result for the laminated structure of FIG. 4B (i.e., 10+20A).

Referring to FIG. 12, it may be confirmed that the switching layer formed (grown) by the ALD process in the embodiment of the present invention is a substance layer including hafnium nitride (HfNₓ) as a main component, and the ratio of Hf and N in the HfNx (Hf:N) is about 1:1 or similar, and includes oxygen (O) at about 10 at %. Additionally, an oxygen-rich HfOₓN_{y} region may exist on the surface (the upper surface) of the switching layer, and the content of oxygen (O) in the HfOₓN_{y} region may be about 50 at % or less, or about 40 at % or less, or about 20 at % or less.

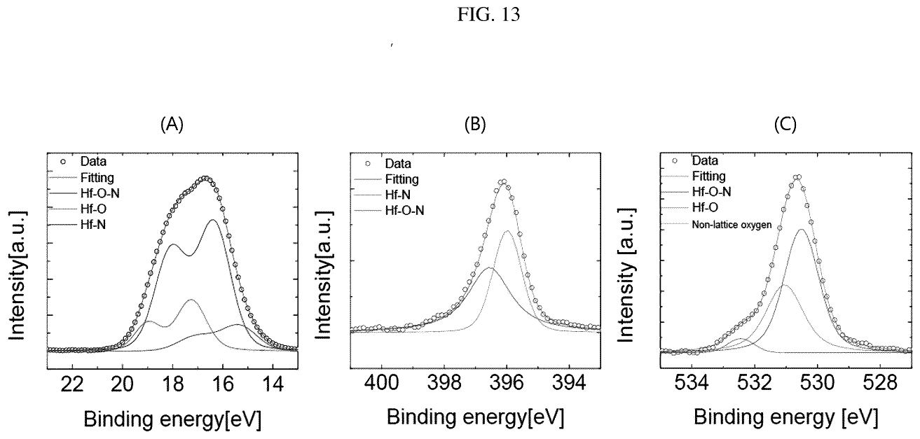

FIG. 13 is a graph showing the results of XPS (X-ray photoelectron spectroscopy) analysis for a switching layer formed by an ALD process in an embodiment of the present invention. The graph (A) of FIG. 13 shows the results for Hf 4f, the graph (B) shows the results for N 1s, and the graph (C) shows the results for O 1s.

Referring to FIG. 13, it may be confirmed that the switching layer formed (grown) by the ALD process in the embodiment of the present invention is a substance layer including hafnium nitride (HfNₓ) as a main component, and is composed of Hf—N, Hf—O—N, and a small amount of Hf—O.

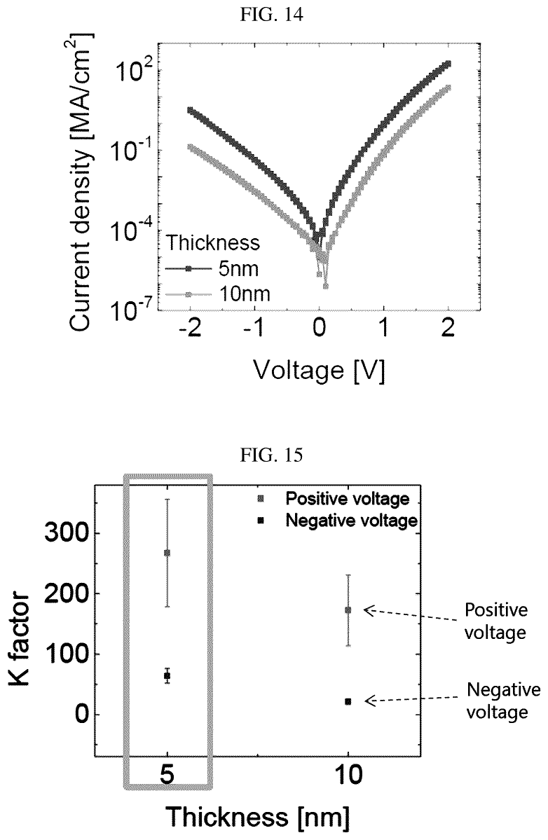

FIG. 14 is a graph showing the voltage-current density characteristics of a selection device as a log scale according to an embodiment of the present invention. The selection device has a Pt (a first electrode)/a switching layer/a Pt (a second electrode) structure, and the switching layer includes hafnium nitride (HfNₓ) as a main component. FIG. 14 includes the results obtained when the thickness of the switching layer is 5 nm and when it is 10 nm.

Referring to FIG. 14, it may be confirmed that the selection device has bipolar switching characteristics. Furthermore, the selection device may exhibit voltage-current density characteristics which are somewhat asymmetrical depending on the polarity during bipolar operation. Depending on the polarity of the voltage applied to the selection device, the conduction mechanism may be different. Furthermore, the selection device according to an embodiment of the present invention implements asymmetric voltage-current density characteristics during bipolar operation without a forming process, and thus has an advantage as a forming-free element, which may be more economical due to rapid processing and process simplification in manufacturing and operating the selection device.

FIG. 15 is a graph showing the results obtained by evaluating the K factor corresponding to the performance index of a selection device according to one embodiment of the present invention. The selection device has a Pt (first electrode)/a switching layer/Pt (second electrode) structure, and the switching layer contains hafnium nitride HfNₓ as a main component. FIG. 15 includes results obtained when the thickness of the switching layer is 5 nm and 10 nm. Here, the K factor is the ratio (that is, I_{ON-voltage}/I_{0.5×ON-voltage}) of the current (I_{ON-voltage}) at the ON voltage to the current (I_{0.5×ON-voltage}) at the voltage corresponding to half of the ON voltage (0.5×ON-voltage), which is a performance index representing the nonlinearity of the selection device.

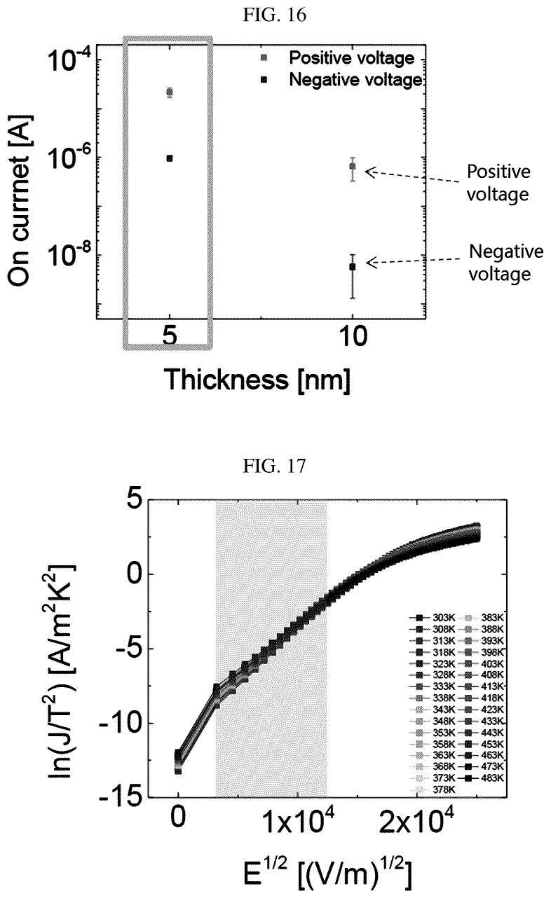

FIG. 16 is a graph showing the results obtained by measuring the ON-current of the selection device according to the embodiment described in FIG. 15.

Referring to FIGS. 15 and 16, it may be confirmed that the selection device has bipolar switching characteristics and has a K factor of about 200 or more under certain conditions. In particular, it may be confirmed that the switching layer has high non-linearity and high current density when the thickness of the switching layer is in the range of about 2 nm to 20 nm, and the switching layer has high non-linearity and high current density when the thickness of the switching layer is about 5 nm as exemplified in FIGS. 15 and 16.

However, the results of FIGS. 14 to 16 are related to a selection device including a switching layer formed by an ALD process under certain conditions, and the characteristics of the selection device may also change as the ALD process conditions change.

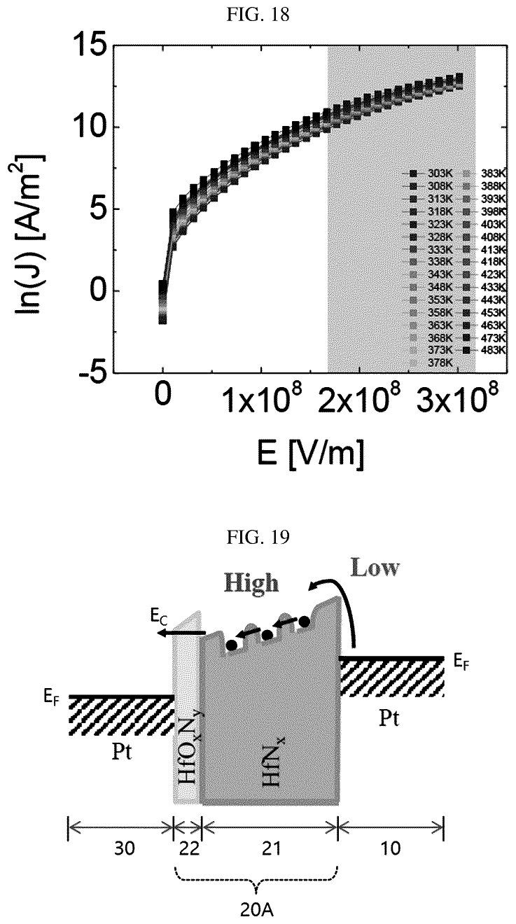

FIG. 17 is a graph showing Schottky emission characteristics in a low electric field region of a selection device according to one embodiment of the present invention. FIG. 18 is a graph showing hopping conduction characteristics in a high electric field region of a selection device according to one embodiment of the present invention.

Referring to FIGS. 17 and 18, conduction of a selection device according to an embodiment of the present invention may be a result of Schottky emission and hopping conduction. In a relatively low electric field region, conduction characteristics due to Schottky emission are mainly exhibited, and in a relatively high electric field region, conduction characteristics due to hopping conduction are mainly exhibited.

FIG. 19 is an energy band diagram for explaining a switching mechanism according to a positive (+) voltage application to a selection device according to one embodiment of the present invention. FIG. 20 is an energy band diagram for explaining a switching mechanism according to a negative (−) voltage application to a selection device according to one embodiment of the present invention. FIG. 19 and FIG. 20 are related to a selection device having the structure of FIG. 2. In FIG. 19 and FIG. 20, EF represents the Fermi level and EC represents the minimum conduction band level.

Referring to FIG. 19, when a relatively low positive (+) voltage is applied, it may be difficult for electrons to flow through the traps of the first layer 21 over the Schottky barrier. However, when a high positive (+) voltage higher than the threshold voltage is applied, electrons may flow well through the traps due to the large potential difference.

Referring to FIG. 20, even when the voltage is increased in the negative (−) direction, threshold switching characteristics, i.e., nonlinear switching characteristics, may appear by a principle similar to that described in FIG. 19.

In the embodiments of FIGS. 19 and 20, as the second layer 22 having a different composition from the first layer 21 is arranged to be in contact with the second electrode 30, the asymmetrical operating characteristics may appear depending on the voltage polarity. Here, the main component of the first layer 21 may be HfNₓ, and the main component of the second layer 22 may be HfOₓN_{y}. To be more specific, when a positive (+) voltage is applied, electrons need to overcome the Schottky barrier with relatively low energy between HfNₓ/Pt, and when a negative (−) voltage is applied, electrons need to overcome the Schottky barrier with relatively high energy between HfOₓN_{y}/Pt. Therefore, in this case, nonlinearity and current level may be higher in positive (+) polarity than in negative (−) polarity.

FIGS. 21 to 24 are graphs showing the results obtained by evaluating the current-voltage (I-V) characteristics of a selection device including a switching layer according to embodiments of the present invention.

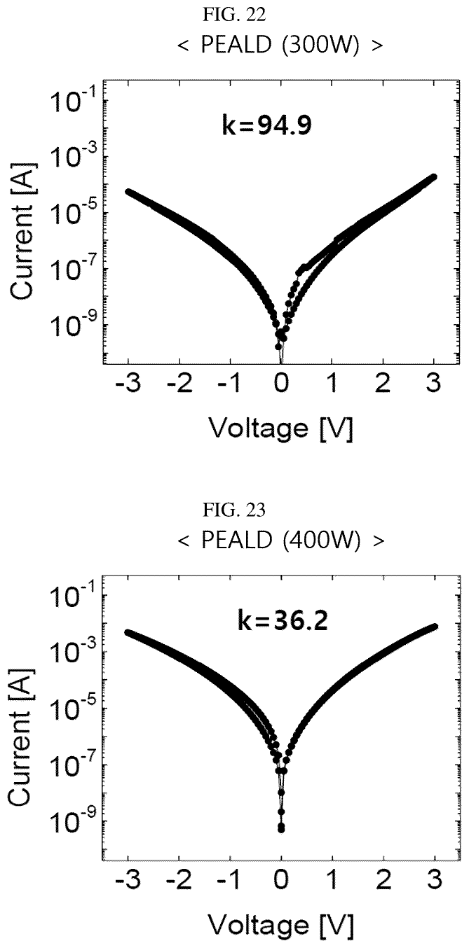

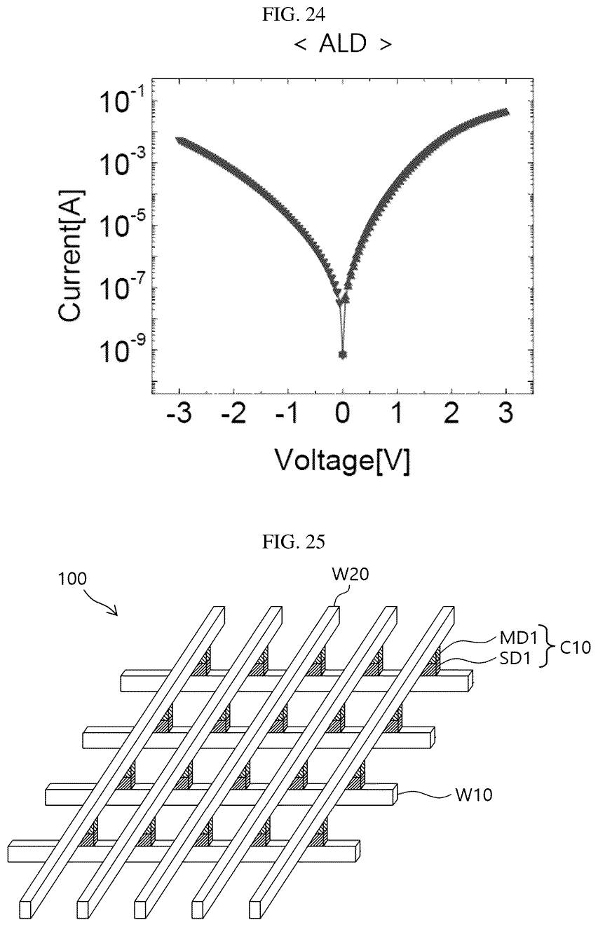

FIG. 21 to FIG. 23 are related to a selection device including a switching layer formed by a PEALD process, and at this time, the thickness of the switching layer (plate type) was all 10 nm. In FIG. 21, the plasma generation power of the PEALD process was 200 W, and in FIG. 22, the plasma generation power of the PEALD process was 300 W, and in FIG. 23, the plasma generation power of the PEALD process was 400 W. Meanwhile, FIG. 24 is related to a selection device including a switching layer formed by a thermal ALD process, and the thickness of the switching layer (plate type) was 10 nm. In FIG. 21 to FIG. 24, the reading voltage for measuring the K factor was all 3 V.

Referring to FIGS. 21 to 24, it may be confirmed that the asymmetry of the I-V curve is significantly reduced in the selection device (FIGS. 21 to 23) including the switching layer formed by the PEALD process when compared to the selection device (FIG. 24) including the switching layer formed by the thermal ALD process. This may be the result obtained by suppressing or preventing the mixing of oxygen (O), and so on through the PEALD process. Therefore, a more uniform switching layer having a higher content of HfNx may be obtained through the PEALD process, symmetrical operating characteristics with respect to bipolarity may be secured, and excellent switching characteristics and nonlinearity may be secured. In particular, when the plasma generation power was 200 W (FIGS. 21) and 300 W (FIG. 22), the K factor was relatively high at about 94.9 and 102.1, respectively. However, the results of FIG. 21 to FIG. 24 are the results obtained when certain ALD process conditions were applied, and the characteristics of the selection device according to the embodiment may be further improved by changing the ALD process conditions.

The selection device according to the embodiments of the present invention described above may be applied to various nonvolatile memory devices. In particular, since the selection device has bipolar switching characteristics, it may be easily applied to various nonvolatile memory devices such as ReRAM (RRAM). A nonvolatile memory element according to an embodiment of the present invention may include a selection device according to the above-described embodiment and a memory element electrically connected to the selection device. The nonvolatile memory element may have, for example, a crossbar array structure, that is, a cross-point array structure. An example thereof is illustrated in FIG. 25.

FIG. 25 is a perspective view illustrating a nonvolatile memory device 100 including a selection device according to one embodiment of the present invention.

Referring to FIG. 25, the nonvolatile memory element 100 may include a plurality of first wires W10 extending in parallel in a first direction and a plurality of second wires W20 extending in parallel in a second direction intersecting the plurality of first wires W10. The plurality of second wires W20 may extend in a direction, for example, orthogonal to the plurality of first wires W10. A nonvolatile memory element 100 may include a memory cell C10 arranged at each intersection between a plurality of first wires W10 and a plurality of second wires W20. The memory cell C10 may include a selection device SD1 and a memory element MD1. For example, the memory element MD1 may be arranged on the selection device SD1 in each memory cell C10, but conversely, the selection device SD1 may also be arranged on the memory element MD1. In each memory cell C10, a selection device SD1 may be electrically connected in series with a memory element MD1.

FIG. 26 is a cross-sectional view illustrating a stacked structure which may be included in the memory cell C10 in FIG. 25.

Referring to FIG. 26, a switching layer 25, a second electrode 35, a memory layer 45, and a third electrode 55 may be sequentially arranged on a first electrode 15. The switching layer 25 may correspond to the switching layer 20, 20A described in FIG. 1 and FIG. 2, and so on. The first electrode 15 and the second electrode 35 may correspond to the first electrode 10 and the second electrode 30 described in FIG. 1 and FIG. 2, respectively. The second electrode 30 may be a floating electrode and may be referred to as an intermediate electrode. The memory layer 45 may be a substance layer whose resistance state is reversibly switched between a low resistance state and a high resistance state by an electrical signal. The memory layer 45 may include a variable resistance substance which may be applied to ReRAM (RRAM). Alternatively, the memory layer 45 may include a memory substance which may be applied to PRAM, MRAM, FRAM, and the like. As a non-limiting example, the memory layer 45 may include at least one of a transition metal oxide, a perovskite compound, and a chalcogenide compound. As a non-limiting example, the transition metal oxide may include Ti oxide, Ni oxide, Ta oxide, Hf oxide, Al oxide, Zr oxide, Cu oxide, Nb oxide, Ta oxide, Ga oxide, Gd oxide, V oxide, Mn oxide, PrCaMn oxide, and the like. Meanwhile, the third electrode 55 may include at least one of a metal and a metal compound.

The first electrode 15, the switching layer 25, and the second electrode 35 may be considered to constitute one selection device. Furthermore, the memory layer 45 may be made to correspond to one memory element. Alternatively, the second electrode 35, the memory layer 45, and the third electrode 55 may be considered to constitute one memory element. Meanwhile, the first electrode 15 may constitute a part of the first wiring W10 of FIG. 25, or may be provided separately from the first wiring W10. Similarly, the third electrode 55 may constitute a part of the second wiring W20 of FIG. 25, or may be provided separately from the second wiring W20.

FIG. 27 is a transmission electron microscopy (TEM) image showing a nonvolatile memory device including a selection device according to one embodiment of the present invention.

Referring to FIG. 27, the nonvolatile memory element may have a structure composed of a Pt layer/HfNₓ layer/Pt layer/HfO₂/Ti layer. This structure may correspond to a structure composed of the first electrode 15/switching layer 25/second electrode 35/memory layer 45/third electrode 55 which is described in FIG. 26. The HfNₓ layer may correspond to the switching layer 20, 20A described in FIGS. 1 and 2, and has a thickness of about 5 nm. The HfO₂ layer is a resistive memory layer and has a thickness of about 6 nm. The Pt layer/HfNₓ layer/Pt layer structure may correspond to a selection device, and the Pt layer/HfO₂ layer/Ti layer structure may correspond to a memory element (here, a resistive memory element).

FIG. 28 is a graph showing the current-voltage (I-V) characteristics of each of the selection devices, memory elements, and the 1S1R structure (i.e., integrated element structure) connected (coupled) to them described in FIG. 27.

Referring to FIG. 28, it may be confirmed that the 1S1R structure operates as a memory and a selector and is capable of bidirectional (polar) switching operation based on the I-V curve of the 1S1R structure in which the selection device 1S and the memory element 1R are combined. The resistance ratio of the 1S1R structure (i.e., integrated device) was about ˜17, the set voltage was about ˜2.2 V, and the non-linearity was about ˜25. Meanwhile, the resistance ratio of only the memory element 1R was approximately ˜ 103, the set voltage was approximately ˜1 V, and the non-linearity of only the selection device 1S was approximately ˜200.FIG. 29 is a graph showing a resistance change characteristics according to the increase in a switching cycle of the 1S1R structure in which the selection device and the memory element described in FIG. 27 are combined. Here, HRS represents a high resistance state, and LRS represents a low resistance state.

Referring to FIG. 29, it may be confirmed that the 1S1R structure according to the embodiment operates stably as a result of continuous measurement while increasing the switching cycle.

FIG. 30 is a planar image showing a crossbar array structure including a selection device according to one embodiment of the present invention.

Referring to FIG. 30, a test was performed on the selection device according to the embodiment by applying the selection device to the intersection of the crossbar array structure corresponding to the 10×10 array. The ON-current and K factor of the selection device were measured while changing the electrode size of the selection device, and the results were as shown in FIG. 31 and FIG. 32.

FIG. 31 is a graph showing the change in ON-current according to the electrode size of the selection device in the array structure described in FIG. 30. FIG. 31 includes results for two voltage polarities when the thickness of the switching layer of the selection device is 5 nm and 10 nm, respectively.

FIG. 32 is a graph showing the change in K factor according to the electrode size of the selection device in the array structure described in FIG. 30. FIG. 32 includes results for two voltage polarities when the thickness of the switching layer of the selection device is 5 nm and 10 nm, respectively.

Referring to FIGS. 31 and 32, it may be confirmed that uniform ON-current characteristics and nonlinear (i.e., K factor) characteristics are exhibited for each electrode size condition. According to one embodiment of the present invention, since a conformal switching layer (a thin film including HfNₓ as a main component) may be easily formed through an ALD process, it may be easy to secure relatively uniform characteristics. According to one embodiment of the present invention, a thin film type selection device may be easily manufactured by using an ALD process, and uniform thickness and composition control of the thin film may be achieved at a relatively low process temperature.

FIG. 33 is a graph showing the results obtained by evaluating the thermal stability of a selection device according to one embodiment of the present invention. The operating characteristics at 27° C. and 100°° C. were evaluated for the selection device (i.e., HfNx-based selector) according to the embodiment.

Referring to FIG. 33, it may be confirmed that the selection device according to the embodiment maintains a nonlinearity (i.e., K factor) characteristic of about 240 during 1000 cycles (switching number) under temperature conditions of 27° C. and 100° C. This may mean that the selection device has excellent thermal stability. Conventional Schottky diodes and PN diodes are relatively sensitive to temperature and have the problem that high-temperature operation is difficult, but the selection device according to an embodiment of the present invention may have excellent thermal stability as compared to the conventional selection devices.

FIG. 34 is a graph showing the results obtained by evaluating the thermal stability of a 1S1R structure (a memory element) including a selection device according to one embodiment of the present invention.

Referring to FIG. 34, it may be confirmed that the 1S1R structure including the selection device according to the embodiment exhibits operating characteristics at almost the same level under temperature conditions of 27° C. and 100°° C., and at this time, the resistance ratio of the 1S1R structure was maintained at a level of about 15 to 17.

The conduction mechanism of The-mentioned selection device may include Schottky emission and hopping conduction, and conduction may be mainly due to hopping conduction in the read voltage range of the K factor. Since the hopping conduction mechanism may have low temperature dependence, the selection device and the memory element including the same may exhibit stable element operation characteristics at both room temperature and high temperature.

According to the embodiments of the present invention described above, a selection device having high non-linearity (i.e., high selectivity) and excellent durability and high-temperature stability may be implemented while using a simple structure and substance composition. In particular, it is possible to easily implement a selection device having a nitride (i.e., hafnium nitride)-based switching layer and having relatively high nonlinearity and excellent bipolar switching characteristics by utilizing a predetermined ALD (ex, PEALD) process. The selection device may be a forming-free element which does not require a forming process, may have uniform thickness and control the composition, and may also have excellent thermal stability. A nonvolatile memory element having excellent operating characteristics, thermal stability, and high integration may be manufactured by applying the selection device according to these embodiments.

In the present specification, the preferred embodiments of the present invention have been disclosed, and although specific terms are used, these are only used in a general sense to easily describe the technological contents of the present invention and to help the understanding of the present invention, and are not used to limit the scope of the present invention. It will be apparent to those of ordinary skill in the art to which the present invention pertains that other modifications based on the technological spirit of the present invention may be implemented in addition to the embodiments disclosed herein. It will be appreciated to those of ordinary skill in the art that a selection device and a manufacturing method thereof according to an embodiment described with reference to FIGS. 1 to 34, and a nonvolatile memory element including the selection device may be variously substituted, changed and modified without departing from the spirit of the present invention. Therefore, the scope of the invention should not be determined by the described embodiments, but should be determined by the technological concepts described in the claims.

### INDUSTRIAL APPLICABILITY

The embodiments of the present invention may be applied to electronic device and semiconductor device technologies. The embodiments of the present invention may be applied to selection devices and memory devices.

1. A selection device comprising:
a first electrode;
a second electrode spaced apart from the first electrode; and
a switching layer disposed between the first electrode and the second electrode, and including hafnium nitride as a main component.

2. The selection device of claim 1, wherein the switching layer is a hafnium nitride layer.

3. The selection device of claim 1, wherein the switching layer further includes oxygen, and a content of the oxygen in the switching layer is 15 at % or less.

4. The selection device of claim 1, wherein the switching layer further includes hafnium oxynitride.

5. The selection device of claim 1, wherein the switching layer includes a first layer portion disposed on the first electrode; and a second layer portion disposed between the first layer portion and the second electrode; and the first layer portion and the second layer portion have different compositions.

6. The selection device of claim 5, wherein the first layer includes hafnium nitride as a main component, and the second layer includes hafnium oxynitride as a main component.

7. The selection device of claim 6, wherein an oxygen content in the second layer is 50 at % or less.

8. The selection device of claim 1, wherein the switching layer has a thickness of 2 to 20 nm.

9. The selection device of claim 1, wherein the selection device has bipolar switching characteristics.

10. A manufacturing method of a selection device comprising:
forming a first electrode;
forming a switching layer including hafnium nitride as a main component on the first electrode; and
forming a second electrode on the switching layer.

11. The manufacturing method of a selection device of claim 10, wherein the switching layer is formed by an ALD (atomic layer deposition) process.

12. The manufacturing method of a selection device of claim 11, wherein the switching layer is formed by a PEALD (plasma enhanced atomic layer deposition) process.

13. The manufacturing method of a selection device of claim 12, wherein the PEALD process uses a hollow cathode plasma (HCP) source as a plasma source.

14. The manufacturing method of a selection device of claim 11, wherein the ALD process includes:
a step of supplying a first precursor which is a source of hafnium (Hf) into a chamber in which the first electrode is arranged;
a first purge step for purging the chamber;
a step for supplying a second precursor which is a source of nitrogen (N) into the chamber; and
a second purge step for purging the chamber.

15. The manufacturing method of a selection device of claim 14, wherein the first precursor includes TEMAHf[tetrakis(ethylmethylamido)hafnium(IV)].

16. The manufacturing method of a selection device of claim 14, wherein the second precursor may include NH₃.

17. The manufacturing method of a selection device of claim 10, wherein the switching layer is a hafnium nitride layer.

18. The manufacturing method of a selection device of claim 10, wherein the switching layer further includes oxygen, and a content of the oxygen in the switching layer is 15 at % or less.

19. The manufacturing method of a selection device of claim 10, wherein the switching layer further includes hafnium oxynitride.

20. The manufacturing method of a selection device of claim 10,
wherein the switching layer includes a first layer portion disposed on the first electrode and a second layer portion disposed between the first layer portion and the second electrode,
wherein the first layer portion includes hafnium nitride as a main component, and the second layer portion includes hafnium oxynitride as a main component.

21. A nonvolatile memory device comprising a selection device as described in any one of claims 1 to 9; and
a memory element electrically connected to the selection device.

22. The nonvolatile memory device of claim 21 comprising a crossbar array structure.

23. The nonvolatile memory device of claim 21 comprising:
a plurality of first wires extending in a first direction;
a plurality of second wires extending in a second direction intersecting the plurality of first wires on the plurality of first wires; and
a memory cell disposed at each intersection between the plurality of first wires and the plurality of second wires, and
wherein the memory cell includes the selection device and the memory element.
